(19) United States
(12) Patent Application Publication
(10) Pub. No.: US 2026/0367501 A1
(43) Pub. Date: Nov. 19, 2026

(54) PHOTOMASK BLANK, PHOTOMASK MANUFACTURED USING PHOTOMASK BLANK, AND METHOD FOR MANUFACTURING SEMICONDUCTOR DEVICE BY USING PHOTOMASK

(71) Applicant: ALPHA ADT CO., LTD., Hwaseong-si, Gyeonggi-do (KR)

(72) Inventors: Ji Sub HWANG, Seoul (KR); Do Weon HWANG, Hwaseong-si (KR)

(73) Assignee: ALPHA ADT CO., LTD., Hwaseong-si, Gyeonggi-do (KR)

(21) Appl. No.: 19/145,755

(22) PCT Filed: Nov. 6, 2023
(86) PCT No.: PCT/KR2023/017641

§ 371 Date: Jul. 3, 2025

(30) Foreign Application Priority Data
Jan. 25, 2023 (KR) 10-2023-0009267

(51) Int. Cl. G03F 1/48; G03F 1/24; G03F 1/52

(52) U.S. Cl. CPC G03F 1/48; G03F 1/24; G03F 1/52

(57) ABSTRACT

A photomask blank capable of preventing intermixing between reflective films by using an interfacial protection film is provided. The photomask blank comprises a substrate including a first surface on which exposure light used in a photo process is incident and a second surface opposite to the first surface, a reflective structure arranged on the first surface of the substrate, including a first reflective film and a second reflective film, which are alternately stacked, and a capping layer on the reflective structure, wherein the first reflective film is a molybdenum (Mo) film, the second reflective film is a silicon (Si) film, each of the first and second reflective films includes a first surface and a second surface, which are opposite to each other, the second surface of the first reflective film and the second surface of the second reflective film face the first surface of the substrate, the first surface of the first reflective film faces the second surface of the second reflective film, and the reflective structure includes a first interfacial protection film that is in contact with the first surface of the first reflective film and the second surface of the second reflective film, and a second interfacial protection film that is in contact with the second surface of the first reflective film and the first surface of the second reflective film.

### TECHNICAL FIELD

The present invention relates to a photomask blank, a photomask manufactured by using the photomask blank and a method of fabricating a semiconductor device using the photomask.

### BACKGROUND ART

Recently, with the rapid advancement of information media, functions of semiconductor devices are developing rapidly. In order to make sure of competitiveness of semiconductor devices, high integration of low-cost and high-quality semiconductor devices is required. For high integration, a spacing between patterns of semiconductor devices is gradually decreasing. A photolithography process using ArF excimer laser, which is currently widely used, as an optical source, has limitations in implementing a line width of 32 nm or less. In order to implement a line width of 32 nm or less, immersion photolithography, double patterning, etc. have been introduced, but they still have limitations.

To solve this problem, a photolithography device using extreme ultraviolet (EUV) as an optical source has been introduced. However, since extreme ultraviolet is greatly attenuated by the atmosphere and has the property of being absorbed by almost all materials, a transmissive photomask used for the ArF photolithography process cannot be used.

Therefore, a photomask including a reflective layer is used in the extreme ultraviolet photolithography process.

### DISCLOSURE OF INVENTION

### Technical Problem

An aspect of the present invention is to provide a photomask blank capable of preventing intermixing between reflective films by using an interfacial protection film.

Another aspect of the present invention is to provide a photomask capable of preventing intermixing between reflective films by using an interfacial protection film.

Other aspect of the present invention is to provide a method of fabricating a semiconductor device using a photomask capable of preventing intermixing between reflective films by using an interfacial protection film.

The aspects of the present invention are not limited to those mentioned above and additional aspects of the present invention, which are not mentioned herein, will be clearly understood by those skilled in the art from the following description of the present invention.

### Technical Solution

According to aspects of the present invention, there is provided a photomask blank comprising, a substrate including a first surface on which exposure light used in a photo process is incident and a second surface opposite to the first surface, a reflective structure disposed on the first surface of the substrate, including a first reflective film and a second reflective film, which are alternately stacked, and a capping layer on the reflective structure, wherein the first reflective film is a molybdenum (Mo) film, the second reflective film is a silicon (Si) film, each of the first and second reflective films includes a first surface and a second surface, which are opposite to each other, the second surface of the first reflective film and the second surface of the second reflective film face the first surface of the substrate, the first surface of the first reflective film faces the second surface of the second reflective film, and the reflective structure includes a first interfacial protection film that is in contact with the first surface of the first reflective film and the second surface of the second reflective film, and a second interfacial protection film that is in contact with the second surface of the first reflective film and the first surface of the second reflective film.

In the photomask blank according to some embodiments of the present invention, each of the first interfacial protection film and the second interfacial protection film includes at least one of molybdenum oxide, silicon oxide, silicon nitride, silicon carbide, boron carbide, or carbon.

In the photomask blank according to some embodiments of the present invention, each of a thickness of the first interfacial protection film and a thickness of the second interfacial protection film is 0.2 nm or more and 1.0 nm or less.

In the photomask blank according to some embodiments of the present invention, each of the first interfacial protection film and the second interfacial protection film is a single material film.

In the photomask blank according to some embodiments of the present invention, a thickness of the first interfacial protection film is the same as a thickness of the second interfacial protection film.

In the photomask blank according to some embodiments of the present invention, the first interfacial protection film includes a first lower interfacial protection film that is in contact with the first surface of the first reflective film, and a first upper interfacial protection film that is in contact with the second surface of the second reflective film, and the second interfacial protection film includes a second lower interfacial protection film that is in contact with the first surface of the second reflective film and a second upper interfacial protection film that is in contact with the second surface of the first reflective film.

In the photomask blank according to some embodiments of the present invention, the first lower interfacial protection film is formed of the same material as that of the second upper interfacial protection film, and the first upper interfacial protection film is formed of the same material as that of the second lower interfacial protection film.

In the photomask blank according to some embodiments of the present invention, a thickness of the first interfacial protection film is the same as a thickness of the second interfacial protection film.

In the photomask blank according to some embodiments of the present invention, a thickness of the first lower interfacial protection film is the same as a thickness of the first upper interfacial protection film, and a thickness of the second lower interfacial protection film is the same as a thickness of the second upper interfacial protection film.

In the photomask blank according to some embodiments of the present invention, a wavelength of the exposure light is λ, a refractive index of molybdenum at the wavelength of the exposure light is n1, a refractive index of silicon at the wavelength of the exposure light is n2, a sum of a thicknesses of the first reflective film and a thickness of the first interfacial protection film is λ/(4*n1), and a sum of a thicknesses of the second reflective film and a thickness of the second interfacial protection film is λ/(4*n2).

In the photomask blank according to some embodiments of the present invention, the capping layer is a ruthenium (Ru) film or a ruthenium compound film.

The photomask blank according to some embodiments of the present invention further comprises a light absorbing layer on the capping layer, wherein the light absorbing layer absorbs the exposure light.

A photomask according to some embodiments of the present invention to achieve the above another object comprises a substrate including a first surface on which exposure light used in a photo process is incident and a second surface opposite to the first surface; a reflective structure disposed on the first surface of the substrate, including a first reflective film and a second reflective film, which are alternately stacked; a capping layer on the reflective structure; and a light absorbing pattern disposed on the capping layer, including an opening through which the exposure light passes, wherein the first reflective film is a molybdenum (Mo) film, the second reflective film is a silicon (Si) film, each of the first interfacial protection film and the second interfacial protection film includes at least one of molybdenum oxide, silicon oxide, silicon nitride, silicon carbide, boron carbide, or carbon, each of the first and second reflective films includes a first surface and a second surface, which are opposite to each other, the second surface of the first reflective film and the second surface of the second reflective film face the first surface of the substrate, the first surface of the first reflective film faces the second surface of the second reflective film, and the reflective structure includes a first interfacial protection film that is in contact with the first surface of the first reflective film and the second surface of the second reflective film, and a second interfacial protection film that is in contact with the second surface of the first reflective film and the first surface of the second reflective film.

In the photomask according to some embodiments of the present invention, a thickness of the first interfacial protection film is the same as a thickness of the second interfacial protection film.

In the photomask according to some embodiments of the present invention, the thickness of the first interfacial protection film is 0.2 nm or more and 1.0 nm or less.

In the photomask according to some embodiments of the present invention, each of the first interfacial protection film and the second interfacial protection film is a single material film.

In the photomask according to some embodiments of the present invention, the first interfacial protection film includes a first lower interfacial protection film that is in contact with the first surface of the first reflective film, and a first upper interfacial protection film that is in contact with the second surface of the second reflective film, the second interfacial protection film includes a second lower interfacial protection film that is in contact with the first surface of the second reflective film and a second upper interfacial protection film that is in contact with the second surface of the first reflective film, the first lower interfacial protection film is formed of the same material as that of the second upper interfacial protection film, and the first upper interfacial protection film is formed of the same material as that of the second lower interfacial protection film.

In the photomask according to some embodiments of the present invention, a wavelength of the exposure light is λ, a refractive index of molybdenum at the wavelength of the exposure light is n1, a refractive index of silicon at the wavelength of the exposure light is n2, a sum of a thicknesses of the first reflective film and a thickness of the first interfacial protection film is λ/(4*n1), and a sum of a thicknesses of the second reflective film and a thickness of the second interfacial protection film is λ/(4*n2).

A method of fabricating a semiconductor according to some embodiments of the present invention to achieve the above other object comprises forming a mask layer on a substrate; and forming a mask pattern on the substrate by etching the mask layer using a photo process using a photomask, wherein the photomask includes a mask substrate including a first surface on which exposure light used in the photo process is incident and a second surface opposite to the first surface, a reflective structure disposed on the first surface of the mask substrate, including a first reflective film and a second reflective film, which are alternately stacked, a capping layer on the reflective structure, and a light absorbing pattern disposed on the capping layer, including an opening through which the exposure light passes, wherein the first reflective film is a molybdenum (Mo) film, the second reflective film is a silicon (Si) film, each of the first interfacial protection film and the second interfacial protection film includes at least one of molybdenum oxide, silicon oxide, silicon nitride, silicon carbide, boron carbide, or carbon, each of the first and second reflective films includes a first surface and a second surface, which are opposite to each other, the second surface of the first reflective film and the second surface of the second reflective film face the first surface of the mask substrate, the first surface of the first reflective film faces the second surface of the second reflective film, and the reflective structure includes a first interfacial protection film that is in contact with the first surface of the first reflective film and the second surface of the second reflective film, and a second interfacial protection film that is in contact with the second surface of the first reflective film and the first surface of the second reflective film.

Details of the other embodiments are included in the detailed description and drawings.

### Advantageous Effects

In the photomask blank according to the embodiment of the present invention, an interfacial protection film is disposed between reflective films having a multi-layered mirror structure, so that intermixing between the reflective films may be prevented.

As intermixing between the reflective films is prevented, reflectivity for exposure light used in a photo process may be prevented from being reduced.

### BRIEF DESCRIPTION OF THE DRAWINGS

FIG. 1 is an example conceptual diagram illustrating an extreme ultraviolet photolithography device using a photomask.

FIG. 2 is a view illustrating a photomask blank according to some embodiments.

FIGS. 3 and 4 are views respectively illustrating an enlarged portion of P of FIG. 2.

FIG. 5 is a view illustrating a photomask blank according to some embodiments.

FIG. 6 is a view illustrating a photomask according to some embodiments.

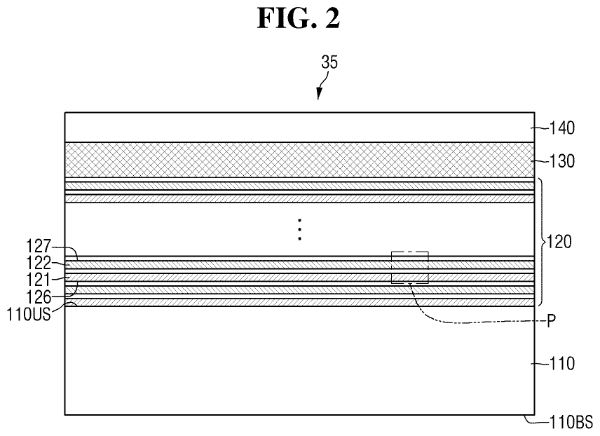

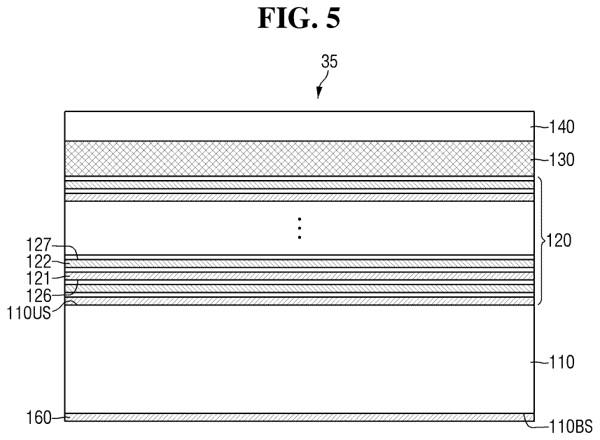

FIG. 5 is a view illustrating a method of controlling a deposition rate using a deposition source system shown in FIGS. 2 to 4.

FIGS. 11 and 12 are graphs illustrating changes in reflectivity of a reflective structure according to changes in a thickness of an interfacial protection film.

FIGS. 13 and 14 are graphs illustrating changes in reflectivity of a reflective structure according to changes in a thickness of an interfacial protection film.

FIGS. 15 and 16 are graphs illustrating changes in reflectivity of a reflective structure according to changes in a thickness of an interfacial protection film.

### MODE FOR THE INVENTION

Advantages and features of the present invention and methods of achieving the advantages and features will be apparent from the following embodiments that will be described in detail with reference to the accompanying drawings. The present invention may, however, be embodied in various forms, and should not be construed as being limited to the embodiments set forth herein. Rather, these embodiments are provided so that the present invention will be thorough and complete, and will fully convey the scope of the present invention to those skilled in the art. Further, the present invention is only defined by the scope of the claims. In the drawings, relative sizes of layers and regions may be exaggerated for clarity of description. Throughout the specification, the same reference numerals refer to the same elements.

It will be understood that when an element is referred to as being “connected to” or “coupled to” another element, it can be directly connected or coupled to another element or intervening elements may be present. In contrast, when an element is referred to as being “directly connected to” or “directly coupled to” another element, there are no intervening elements present. Throughout the specification, the same reference numerals refer to the same elements. As used herein, the term “and/or” includes any and all combinations of one or more of the associated listed items.

Spatially relative terms, such as “below,” “beneath,” “lower,” “above,” “upper” and the like, may be used herein for ease of explanation to illustrate one element or feature's relationship to another element or feature as illustrated in the drawings. It will be understood that the spatially relative terms are intended to encompass different orientations of the device in use or in operation, in addition to the orientation depicted in the drawings.

It will be understood that, although the terms “first,” “second,” etc. may be used herein to describe various elements, components, and/or sections, these elements, components, and/or sections should not be limited by these terms. These terms are only used to distinguish one element, component or section from another element, component or section. Thus, “a first element,” “first component” or “first section” discussed below could be termed a second element, second component or second section without departing from the technical spirits of the present invention.

The terms used in the present specification are for the purpose of embodiments, and are not intended to be limit the present invention. In the present specification, unless referred to the contrary, the singular forms are intended to include the plural forms. The terms “comprises” and/or “comprising” used herein specify the presence of stated elements, steps, operations and/or elements but do not preclude the presence or addition of one or more other elements, steps, operations and/or elements.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

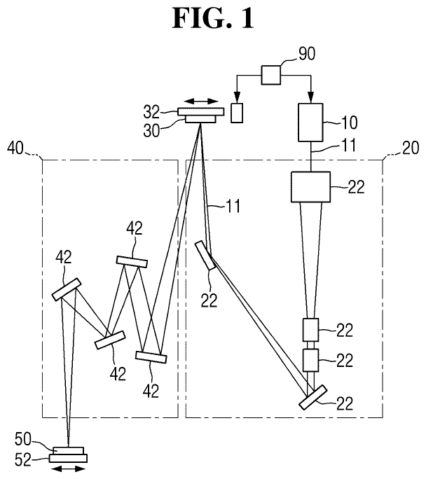

FIG. 1 is an example conceptual diagram illustrating an extreme ultraviolet photolithography device using a photomask.

Referring to FIG. 1, the extreme ultraviolet photolithography device according to some embodiments may include an optical source unit 10, a condenser unit 20, a projection unit 40, and a control unit 90.

The optical source unit 10 may generate exposure light 11. The exposure light 11 may include extreme ultraviolet (EUV) having a wavelength of about 10 nm to about 14 nm. For example, the optical source unit 10 may generate extreme ultraviolet having a wavelength of about 13.5 nm by using plasma generated by irradiating a CO₂ laser to tin (Sn). The exposure light 11 generated from the optical source unit 10 may be provided to the condenser unit 20.

The condenser unit 20 may guide the exposure light 11 generated by the optical source unit 10 toward a photomask 30. The condenser unit 20 may include a condenser optics 22 (for example, a lens and/or a mirror). The condenser optics 22 may collect and reflect the exposure light 11 to guide the exposure light 11 toward the photomask 30. The exposure light 11 may be obliquely incident on the photomask 30 through the condenser unit 20.

Although not shown, a pellicle may be disposed on the photomask 30 to prevent contamination of the photomask 30. In some embodiments, the photomask 30 may move by being mounted on a mask stage 32. The optical source unit 10 and the mask stage 32 may be controlled by the control unit 90.

The exposure light 11 incident on the photomask 30 may be reflected by the photomask 30 and may be incident on the projection unit 40. The projection unit 40 may project a pattern image of the photomask 30 onto a first substrate 50. The first substrate 50 may be a wafer on which an integrated circuit is formed. For example, the first substrate 50 may include a photoresist film that reacts to the exposure light 11. The exposure light 11 may be used in a photo process.

The projection unit 40 may include a projection optics 42 (e.g., a lens and/or a mirror). The projection optics 42 may reduce a pattern image on the photomask 30 to a predetermined magnification (e.g., four times, six times or eight times) by using the exposure light 11 reflected from the photomask 30, and may project the pattern image onto the first substrate 50.

In some embodiments, the first substrate 50 may be mounted on a substrate stage 52. The substrate stage 52 may move the first substrate 50 to change an exposure region (or an exposure position) of the first substrate 50.

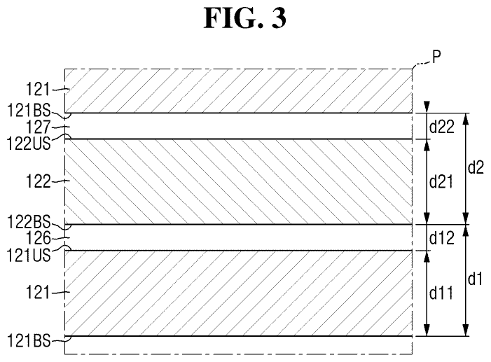

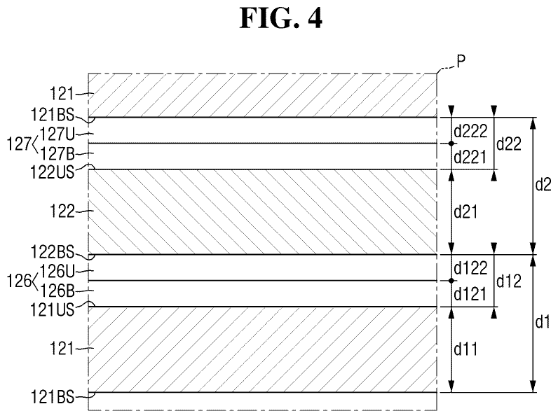

FIG. 2 is a view illustrating a photomask blank according to some embodiments. FIGS. 3 and 4 are views respectively illustrating an enlarged portion of P of FIG. 2.

For example, a photomask blank 35 may be a substrate for manufacturing a photomask (30 of FIG. 1) that may be mounted on a photolithography device that uses extreme ultraviolet as an optical source.

Referring to FIGS. 2 to 4, the photomask blank 35 according to some embodiments may include a mask substrate 110, a reflective structure 120, a capping layer 130, and a light absorbing layer 140.

The mask substrate 110 may be made of a dielectric material, glass, semiconductor, or a metal material. In some embodiments, the mask substrate 110 may be made of a material having a low thermal expansion coefficient. For example, the mask substrate 110 may have a thermal expansion coefficient of 0±1.0×10⁻⁷/°C at 20 °C.

In addition, the mask substrate 110 may be made of a material having excellent smoothness, flatness and resistance to cleaning solutions. For example, the mask substrate 110 may be made of low thermal expansion material (LTEM) glass, such as synthetic quartz glass, quartz glass, alumino silicate glass, soda lime glass, SiO₂—TiO₂-based glass (binary-based glass (SiO₂—TiO₂) and ternary-based glass (SiO₂—TiO₂—SnO₂)), crystallized glass precipitated with a β quartz solid solution, single crystal silicon, or SiC. The mask substrate 110 included in the photomask blank 35 may be required to have low thermal expansion characteristics. Accordingly, in the photomask blank 35 according to some embodiments, the mask substrate 110 may be made of, for example, a multi-component glass material.

The mask substrate 110 may include a first surface 110US and a second surface 110BS, which are opposite to each other. The first surface 110US of the mask substrate may be a surface on which exposure light (11 of FIG. 1) used in a photo process is incident.

For example, the first surface 110US of the mask substrate may have flatness of about 50 nm or less, but is not limited thereto. The second surface 110BS of the mask substrate may have flatness of about 500 nm or less, but is not limited thereto. Also, the first surface 110US of the mask substrate 110 and the second surface 110BS of the mask substrate may have surface roughness of root mean square (RMS) of about 0.15 nm or less, but are not limited thereto.

The reflective structure 120 may be disposed on the first surface 110US of the mask substrate. The reflective structure 120 may reflect the exposure light (11 of FIG. 1). For example, the reflective structure 120 may reflect extreme ultraviolet (EUV). The reflective structure 120 may have a multi-layered mirror structure. In the reflective structure 120, a material layer having a high refractive index and a material layer having a low refractive index may be alternately stacked a plurality of times.

The reflective structure 120 may include a first reflective film 121 and a second reflective film 122, which are alternately stacked. The reflective structure 120 may include a first reflective film 121 and a second reflective film 122, which are repeatedly formed at a period of 20 to 60.

As an example, the first reflective film 121 may be a molybdenum (Mo) film, and the second reflective film 122 may be a silicon (Si) film. As another example, the first reflective film 121 may be a silicon film, and the second reflective film 122 may be a molybdenum film. In the following description, it is described that the first reflective film 121 is a molybdenum film and the second reflective film 122 is a silicon film.

The first reflective film 121 may include a first surface 121US and a second surface 121BS, which are opposite each other. The second reflective film 122 may include a first surface 122US and a second surface 122BS, which are opposite each other. The second surface 121BS of the first reflective film and the second surface 122BS of the second reflective film may respectively face the first surface 110US of the mask substrate. The first surface 121US of the first reflective film may face the second surface 122BS of the second reflective film. Also, the second surface 121BS of the first reflective film may face the first surface 122US of the second reflective film.

The reflective structure 120 may include a first interfacial protection film 126 and a second interfacial protection film 127. The first interfacial protection film 126 and the second interfacial protection film 127 may be disposed between the first reflective film 121 and the second reflective film 122, which are adjacent thereto.

The first interfacial protection film 126 may be disposed between the first surface 121US of the first reflective film and the second surface 122BS of the second reflective film. The first interfacial protection film 126 may be in contact with the first surface 121US of the first reflective film and the second surface 122BS of the second reflective film. The first surface 121US of the first reflective film is not in contact with the second surface 122BS of the second reflective film.

The second interfacial protection film 127 may be disposed between the second surface 121BS of the first reflective film and the first surface 122US of the second reflective film. The second interfacial protection film 127 may be in contact with the second surface 121BS of the first reflective film and the first surface 122US of the second reflective film. The second surface 121BS of the first reflective film is not in contact with the first surface 122US of the second reflective film.

In FIGS. 3 and 4, a sum d1 of a thickness d11 of the first reflective film 121 and a thickness d12 of the first interfacial protection film 126 may satisfy the relation of Equation 1. A sum d2 of a thickness d21 of the second reflective film 122 and a thickness d22 of the second interfacial protection film 127 may satisfy the relation of Equation 2.

$$d 1 = \frac{λ}{4 {n}_{1}} \qquad [ Equation 1 ]$$

$$d 2 = \frac{λ}{4 {n}_{2}} \qquad [ Equation 2 ]$$

In the Equations 1 and 2, λ represents a wavelength of the exposure light (11 of FIG. 1) used in the photo process. In the Equation 1, n₁ may be a refractive index of the first reflective film 121 at the wavelength λ of the exposure light, that is, a refractive index of molybdenum. In the Equation 2, n₂ may be a refractive index of the second reflective film 122 at the wavelength λ of the exposure light, that is, a refractive index of silicon. For example, when the wavelength λ of the exposure light is 13.5 nm, the refractive index n₁ of molybdenum may be 0.9238, and the refractive index n₂ of silicon may be 0.9990.

Each of the thickness d12 of the first interfacial protection film 126 and the thickness d22 of the second interfacial protection film 127 may be 0.2 nm or more and 1.0 nm or less. For example, the thickness d12 of the first interfacial protection film 126 may be the same as the thickness d22 of the second interfacial protection film 127.

Each of the first interfacial protection film 126 and the second interfacial protection film 127 may include at least one of molybdenum oxide, silicon oxide, silicon nitride, silicon carbide, boron carbide (B₄C), or carbon.

In FIGS. 2 and 3, each of the first interfacial protection film 126 and the second interfacial protection film 127 may be a single material film.

As an example, a material included in the first interfacial protection film 126 may be different from a material included in the second interfacial protection film 127. The first interfacial protection film 126 may be formed of a material different from that of the second interfacial protection film 127.

As another example, the material included in the first interfacial protection film 126 may be the same as the material included in the second interfacial protection film 127. The first interfacial protection film 126 may be formed of the same material as that of the second interfacial protection film 127.

In FIGS. 2 and 4, each of the first interfacial protection film 126 and the second interfacial protection film 127 may be a multi-material film. The number of films included in the first interfacial protection film 126 is equal to the number of films included in the second interfacial protection film 127.

The first interfacial protection film 126 may include a first lower interfacial protection film 126B and a first upper interfacial protection film 126U. The first lower interfacial protection film 126B may be in contact with the first surface 121US of the first reflective film. The first upper interfacial protection film 126U may be in contact with the second surface 122BS of the second reflective film.

The second interfacial protection film 127 may include a second lower interfacial protection film 127B and a second upper interfacial protection film 127U. The second lower interfacial protection film 127B may be in contact with the first surface 122US of the second reflective film. The second upper interfacial protection film 12U may be in contact with the second surface 121BS of the first reflective film.

The first lower interfacial protection film 126B may be formed of a material different from that of the first upper interfacial protection film 126U. The second lower interfacial protection film 127B may be formed of a material different from that of the second upper interfacial protection film 127U.

For example, the first lower interfacial protection film 126B may be formed of the same material as that of the second upper interfacial protection film 127U. The first lower interfacial protection film 126B and the second upper interfacial protection film 127U, which are in contact with the first reflective film 121, may be formed of the same material.

For example, the second lower interfacial protection film 127B may be formed of the same material as that of the first upper interfacial protection film 126U. The second lower interfacial protection film 127B and the first upper interfacial protection film 126U, which are in contact with the second reflective film 122, may be formed of the same material.

For example, a thickness d121 of the first lower interfacial protection film 126B may be the same as a thickness d122 of the first upper interfacial protection film 126U. A thickness d221 of the second lower interfacial protection film 127B may be the same as a thickness d222 of the second upper interfacial protection film 127U. Also, the thickness d121 of the first lower interfacial protection film 126B may be the same as the thickness d222 of the second upper interfacial protection film 127U. The thickness d221 of the second lower interfacial protection film 127B may be the same as the thickness d122 of the first upper interfacial protection film 126U.

The capping layer 130 may be disposed on the reflective structure 120. For example, the capping layer 130 may be in contact with the reflective structure 120. The reflective structure 120 may be disposed between the capping layer 130 and the mask substrate 110.

The capping layer 130 may serve to protect the reflective structure 120 from mechanical and/or chemical damages.

The capping layer 130 may be made of ruthenium (Ru) or a ruthenium compound. The capping layer 130 may be a ruthenium film or a ruthenium compound film. The ruthenium compound may be made of a compound including ruthenium (Ru) and at least one selected from the group consisting of Nb, Zr, Mo, Y, B and La.

The light absorbing layer 140 may be disposed on the capping layer 130. The light absorbing layer 140 may be made of a material having low reflectivity of the exposure light (11 of FIG. 1) while absorbing the exposure light (11 of FIG. 1). For example, the light absorbing layer 140 may be made of a material having low reflectivity of the extreme ultraviolet light while absorbing the extreme ultraviolet light. The light absorbing layer 140 may be made of a material having excellent chemical resistance. In addition, the light absorbing layer 140 may be made of a material that may be removed by etching or the like.

The light absorbing layer 140 may be made of a material including Ta as a main component. In the photomask blank 35 according to some embodiments, the light absorbing layer 140 may include a main component of tantalum (Ta), and at least one of hafnium (Hf), silicon (Si), zirconium (Zr), germanium (Ge), boron (B), nitrogen (N), or hydrogen (H). For example, the light absorbing layer 140 may include TaN, TaHf, TaHfN, TaBSi, TaBSiN, TaB, TaBN, TaSi, TaSiN, TaGe, TaGeN, TaZr, TaZrN, or their combination, but is not limited thereto.

In FIGS. 2, 3, 11 and 12, each of the first interfacial protection film 126 and the second interfacial protection film 127 may be a single material film. The first interfacial protection film 126 may be formed of molybdenum oxide, and the second interfacial protection film 127 may be formed of silicon oxide. The reflective structure 120 includes a first reflective film 121 and a second reflective film 122 at a period of 40.

FIGS. 11 and 12 are graphs illustrating changes in reflectivity of a reflective structure according to changes in a thickness of the interfacial protection film. FIGS. 11 and 12 illustrate changes in reflectivity of the reflective structure 120 according to changes in a thickness of the first interfacial protection film 126 and a thickness of the second interfacial protection film 127. A thickness δ of the first interfacial protection film 126 and a thickness δ of the second interfacial protection film 127 change to 0.2 nm, 0.4 nm, 0.6 nm, 0.8 nm and 1.0 nm.

When the thickness δ of the first interfacial protection film 126 and the thickness δ of the second interfacial protection film 127 are 0 nm, reflectivity of the reflective structure 120 with respect to light having a wavelength of 13.50 nm may be 71.85%. When the thickness δ of the first interfacial protection film 126 and the thickness δ of the second interfacial protection film 127 are 0.2 nm, reflectivity of the reflective structure 120 with respect to light having a wavelength of 13.50 nm may be 71.43%. In this case, reflectivity of the reflective structure 120 may be an Essential Macleod simulation result.

As the thickness δ of the first interfacial protection film 126 and the thickness δ of the second interfacial protection film 127 increase, reflectivity of the reflective structure 120 with respect to light having a wavelength of 13.50 nm may decrease. However, when the thickness δ of the first interfacial protection film 126 and the thickness δ of the second interfacial protection film 127 are 0.4 nm, reflectivity of the reflective structure 120 with respect to light having a wavelength of 13.50 nm is greater than 70%. Also, when the thickness δ of the first interfacial protection film 126 and the thickness δ of the second interfacial protection film 127 are 1.0 nm, reflectivity of the reflective structure 120 with respect to light having a wavelength of 13.50 nm is greater than 65%.

In FIGS. 2, 4, 13 to 16, each of the first interfacial protection film 126 and the second interfacial protection film 127 may be a double material film. The reflective structure 120 includes a first reflective film 121 and a second reflective film 122 at a period of 40.

In FIGS. 13 and 14, the first lower interfacial protection film 126B and the second upper interfacial protection film 127U may be formed of molybdenum oxide, and the first upper interfacial protection film 126U and the second lower interfacial protection film 127B may be formed of silicon oxide.

In FIGS. 15 and 16, the first lower interfacial protection film 126B and the second upper interfacial protection film 127U may be formed of molybdenum oxide, and the first upper interfacial protection film 126U and the second lower interfacial protection film 127B may be formed of silicon nitride.

FIGS. 13 and 14 are graphs illustrating changes in reflectivity of a reflective structure according to changes in a thickness of an interfacial protection film. FIGS. 15 and 16 are graphs illustrating changes in reflectivity of a reflective structure according to changes in a thickness of an interfacial protection film. FIGS. 13 to 16 illustrate changes in reflectivity of the reflective structure 120 according to changes in the thickness of the first interfacial protection film 126 and the thickness of the second interfacial protection film 127. The thickness δ of the first interfacial protection film 126 and the thickness δ of the second interfacial protection film 127 change to 0.2 nm, 0.4 nm, 0.6 nm, 0.8 nm and 1.0 nm. That is, the thickness of the first lower interfacial protection film 126B and the thickness of the first upper interfacial protection film 126U change to 0.1 nm, 0.2 nm, 0.3 nm, 0.4 nm and 0.5 nm.

In FIGS. 13 and 14, when the thickness δ of the first interfacial protection film 126 and the thickness δ of the second interfacial protection film 127 are 0 nm, reflectivity of the reflective structure 120 with respect to light having a wavelength of 13.50 nm may be 71.85%. When the thickness δ of the first interfacial protection film 126 and the thickness δ of the second interfacial protection film 127 are 0.2 nm, reflectivity of the reflective structure 120 with respect to light having a wavelength of 13.50 nm may be 70.08%. That is, when the thickness of the first lower interfacial protection film 126B and the thickness of the second upper interfacial protection film 126U are 0.1 nm, reflectivity of the reflective structure 120 with respect to light having a wavelength of 13.50 nm may be 70.08%.

As the thickness δ of the first interfacial protection film 126 and the thickness δ of the second interfacial protection film 127 increase, reflectivity of the reflective structure 120 with respect to light having a wavelength of 13.50 nm may decrease. When the thickness δ of the first interfacial protection film 126 and the thickness δ of the second interfacial protection film 127 are 0.6 nm, reflectivity of the reflective structure 120 with respect to light having a wavelength of 13.50 nm is greater than 65%. Also, when the thickness δ of the first interfacial protection film 126 and the thickness δ of the second interfacial protection film 127 are 1.0 nm, reflectivity of the reflective structure 120 with respect to light having a wavelength of 13.50 nm is greater than 60%.

In FIGS. 15 and 16, when the thickness δ of the first interfacial protection film 126 and the thickness δ of the second interfacial protection film 127 are 0 nm, reflectivity of the reflective structure 120 with respect to light having a wavelength of 13.50 nm may be 71.85%. When the thickness δ of the first interfacial protection film 126 and the thickness δ of the second interfacial protection film 127 are 0.2 nm, reflectivity of the reflective structure 120 with respect to light having a wavelength of 13.50 nm may be 70.34%. That is, when the thickness of the first lower interfacial protection film 126B and the thickness of the second upper interfacial protection film 126U are 0.1 nm, reflectivity of the reflective structure 120 with respect to light having a wavelength of 13.50 nm may be 70.34%.

As the thickness δ of the first interfacial protection film 126 and the thickness δ of the second interfacial protection film 127 increase, reflectivity of the reflective structure 120 with respect to light having a wavelength of 13.50 nm may decrease. When the thickness δ of the first interfacial protection film 126 and the thickness δ of the second interfacial protection film 127 are 0.6 nm, reflectivity of the reflective structure 120 with respect to light having a wavelength of 13.50 nm is greater than 65%. Also, when the thickness δ of the first interfacial protection film 126 and the thickness δ of the second interfacial protection film 127 are 1.0 nm, reflectivity of the reflective structure 120 with respect to light having a wavelength of 13.50 nm is greater than 60%.

When the first reflection film 121 and the second reflection film 122 are in contact with each other, a boundary film formed by mixing the first reflection film 121 with the second reflection film 122 may be formed between the first reflection film 121 and the second reflection film 122. The boundary film formed by mixing the first reflection film 121 with the second reflection film 122 reduces reflectivity of the reflective structure 120. That is, due to the boundary film formed by mixing the first reflection film 121 with the second reflection film 122, reflectivity of the reflective structure 120 actually manufactured becomes lower than that of the reflective structure 120 obtained by simulation.

However, since the first interfacial protection film 126 and the second interfacial protection film 127 are disposed between the first reflective film 121 and the second reflective film 122, the first reflective film 121 and the second reflective film 122 may not be mixed with each other. That is, the first interfacial protection film 126 and the second interfacial protection film 127 may prevent the boundary film from being formed between the first reflective film 121 and the second reflective film 122.

On the other hand, a difference between reflectivity of the reflective structure 120 including the interfacial protection film and reflectivity of the reflective structure 120 for not including the interfacial protection film is very small. That is, since the interfacial protection film is applied between the first reflective film 121 and the second reflective film 122, chemical stability of the reflective structure 120 may be improved and at the same time optical characteristics may be maintained. In this case, since the first reflective film 121 and the second reflective film 122 do not react with each other so as not to form a boundary film, chemical stability of the reflective structure 120 may be improved. Since the boundary film is not formed between the first reflective film 121 and the second reflective film 122, reflectivity of the reflective structure 120 may be prevented from being reduced. Accordingly, optical characteristics of the reflective structure 120 may be maintained.

FIG. 5 is a view illustrating a photomask blank according to some embodiments. For convenience of description, a difference from that described with reference to FIGS. 2 to 4 will be mainly described.

Referring to FIG. 5, a photomask blank 35 according to some embodiments may further include a conductive coating film 160.

The conductive coating film 160 may be disposed on the second surface 110BS of the mask substrate. The conductive coating film 160 may be used to fix a photomask (30 of FIG. 1) manufactured by using a photomask blank to an electrostatic chuck of a lithography device during a photolithography process.

The conductive coating film 160 may include a chromium (Cr)-containing material or a tantalum (Ta)-containing material, which have conductivity. For example, the conductive coating film 160 may be made of at least one of Cr, CrN, and TaB.

Alternatively, the conductive coating film 160 may include a metal oxide or a metal nitride, which have conductivity. For example, the conductive coating film 160 may be made of at least one of titanium nitride (TiN), zirconium nitride (ZrN), hafnium nitride (HfN), ruthenium oxide (RuO₂), zinc oxide (ZnO₂), or iridium oxide (IrO₂).

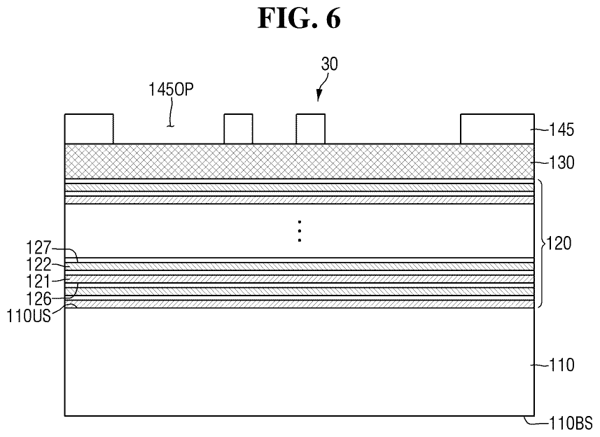

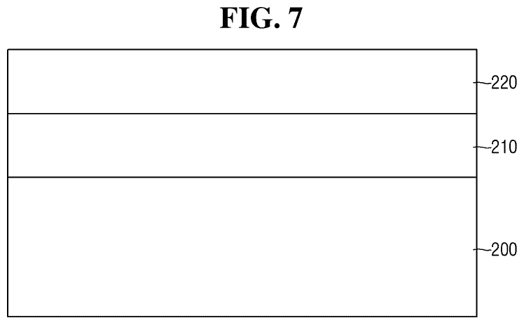

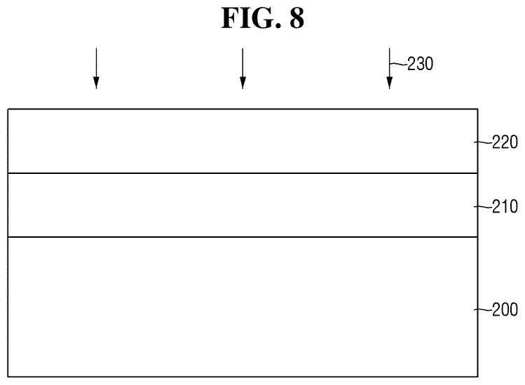

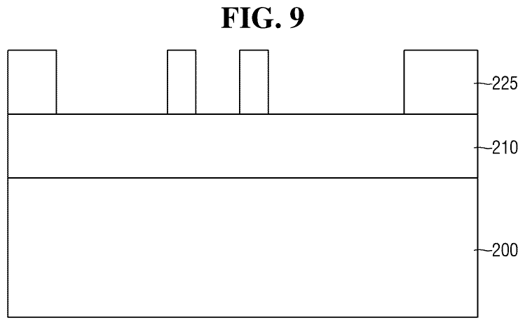

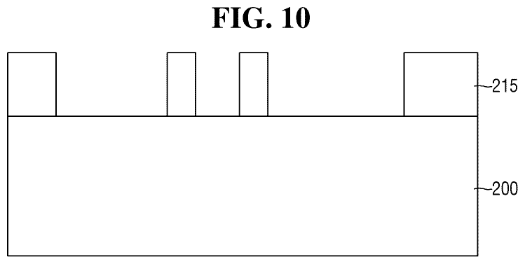

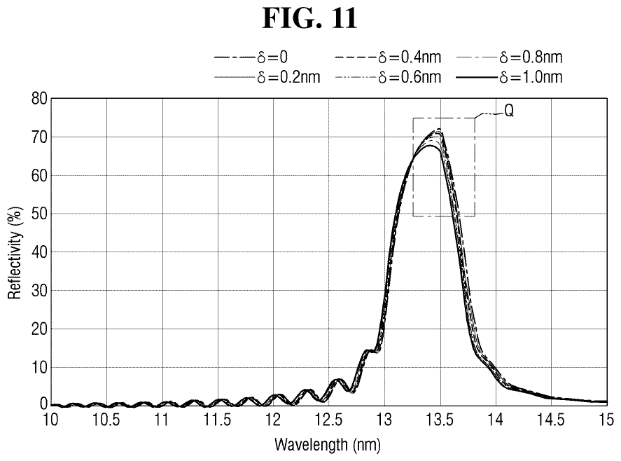

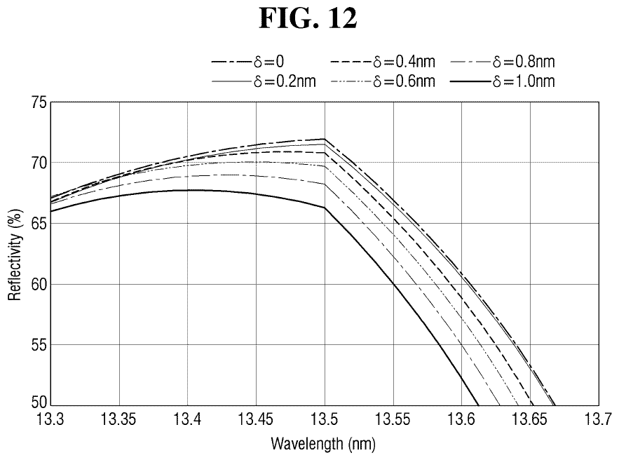

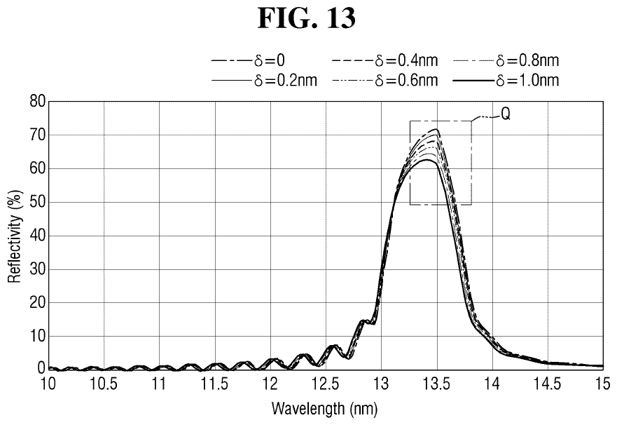

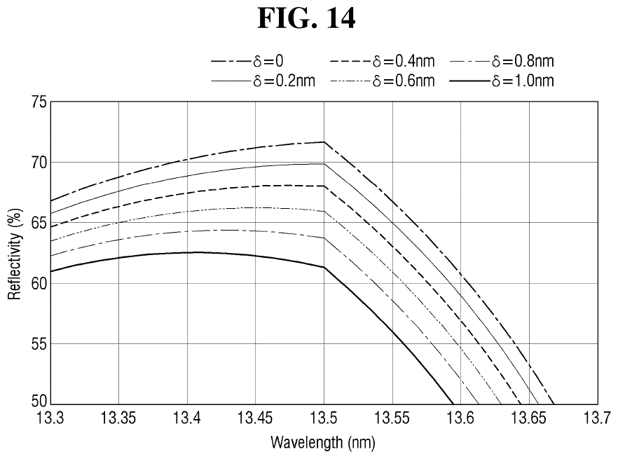

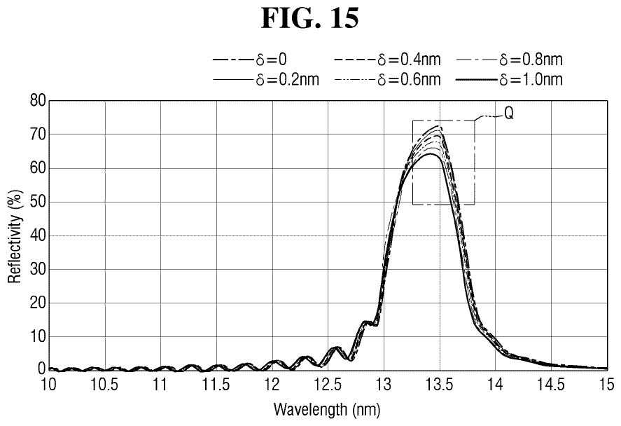

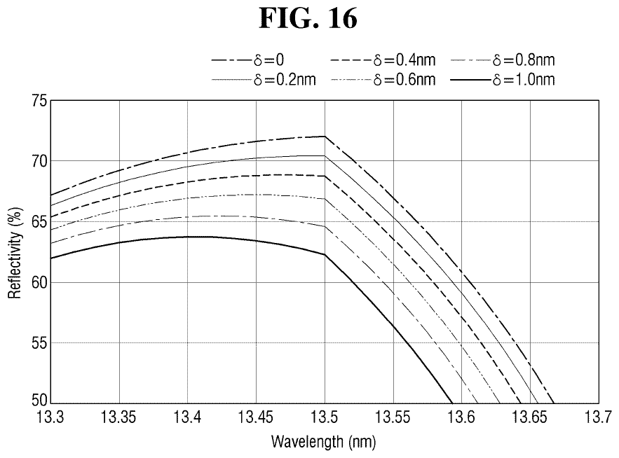

FIG. 6 is a view illustrating a photomask according to some embodiments.

The photomask 30 according to some embodiments may be a reflective photomask that may be used in a photolithography process using an EUV wavelength range, for example, a wavelength of exposure light of about 13.5 nm.

In addition, the photomask 30 according to some embodiments may be manufactured by patterning the light absorbing layer 140 included in the photomask blank 35 of FIGS. 2 to 5. For example, FIG. 6 may be manufactured by patterning the light absorbing layer 140 of FIG. 2.

In the photomask 30 according to some embodiments, descriptions of the mask substrate 110, the reflective structure 120 and the capping layer 130 are substantially similar to those described in FIGS. 2 to 4, and thus will be omitted.

Referring to FIG. 6, the photomask 30 according to some embodiments may include a mask substrate 110, a reflective structure 120, a capping layer 130, and a light absorbing pattern 145.

The light absorbing pattern 145 may be disposed on the capping layer 130. The light absorbing pattern 145 may include an opening 145OP through which the exposure light (11 of FIG. 1) passes.

Although not shown, a low reflective layer pattern may be further disposed on the light absorbing pattern 145.

FIGS. 7 to 10 are views illustrating intermediate steps to describe a method of fabricating a semiconductor device according to some embodiments.

A method of fabricating a semiconductor device according to some embodiments may be a fabricating method using the photomask of FIG. 6.

Referring to FIG. 7, a mask layer 210 may be formed on a second substrate 200.

The second substrate 200 may be a silicon substrate, or may include other material, for example, silicon-on-insulator (SOI), silicon germanium, silicon germanium on insulator (SGOI), indium antimonide, lead telluride, indium arsenide, indium phosphide, gallium arsenide, or gallium antimonide, but is not limited thereto.

The second substrate 200 may include a circuit element including a conductive pattern and a semiconductor pattern. The second substrate 200 may include an insulating film and a metal line in the insulating film.

When the second substrate 200 includes a circuit element, the circuit element may be, for example, a fin-type transistor (FinFET) including a fin-type pattern channel region, a tunneling FET, a transistor including nanowires, a transistor including nanosheets, or a three-dimensional (3D) transistor, a bipolar junction transistor, a lateral diffused metal-oxide semiconductor (LDMOS) transistor, or a planar transistor, but is not limited thereto.

The mask layer 210 may include at least one of an insulating material, a semiconductor material, or a conductive material.

A photoresist layer 220 may be formed on the mask layer 210.

Referring to FIGS. 8 to 10, the mask layer 210 may be etched using a photo process 230 using the photomask (30 of FIGS. 1 and 6). Accordingly, a mask pattern 215 may be formed on the second substrate 200.

In FIG. 8, an element pattern may be transferred to the photoresist layer 220 by using the photo process 230. The photo process 230 may use the exposure light (11 of FIG. 1) reflected from the photomask 30.

In FIG. 9, the photoresist pattern 225 may be formed on the mask layer 210 by developing the element pattern transferred to the photoresist layer 220.

In FIG. 10, the mask layer 210 may be etched using the photoresist pattern 225. As a result, the mask pattern 215 may be formed on the second substrate 200. The photoresist pattern 225 may be removed.

As an example, a portion of the second substrate 200 may be etched using the mask pattern 215. As another example, the mask pattern 215 itself may be used as a portion of a semiconductor element.

Although the embodiments of the present invention have been described with reference to the accompanying drawings, it will be apparent to those skilled in the art that the present invention may be embodied in other specific forms without departing from the spirit and essential characteristics of the specification. The above embodiments are therefore to be construed in all aspects as illustrative and not restrictive.

1. A photomask blank comprising:
a substrate including a first surface on which exposure light used in a photo process is incident, and a second surface opposite to the first surface;
a reflective structure disposed on the first surface of the substrate, and including a first reflective film and a second reflective film which are alternately stacked; and
a capping layer on the reflective structure,
wherein the first reflective film is a molybdenum (Mo) film,
the second reflective film is a silicon (Si) film,
each of the first and second reflective films includes a first surface and a second surface which are opposite to each other,
the second surface of the first reflective film and the second surface of the second reflective film face the first surface of the substrate,
the first surface of the first reflective film faces the second surface of the second reflective film, and
the reflective structure includes a first interfacial protection film that is in contact with the first surface of the first reflective film and the second surface of the second reflective film, and a second interfacial protection film that is in contact with the second surface of the first reflective film and the first surface of the second reflective film.

2. The photomask blank of claim 1, wherein each of the first interfacial protection film and the second interfacial protection film includes at least one of molybdenum oxide, silicon oxide, silicon nitride, silicon carbide, boron carbide, or carbon.

3. The photomask blank of claim 1, wherein each of a thickness of the first interfacial protection film and a thickness of the second interfacial protection film is 0.2 nm or more and 1.0 nm or less.

4. The photomask blank of claim 1, wherein each of the first interfacial protection film and the second interfacial protection film is a single material film.

5. The photomask blank of claim 4, wherein a thickness of the first interfacial protection film is the same as a thickness of the second interfacial protection film.

6. The photomask blank of claim 1, wherein the first interfacial protection film includes a first lower interfacial protection film that is in contact with the first surface of the first reflective film, and a first upper interfacial protection film that is in contact with the second surface of the second reflective film, and
the second interfacial protection film includes a second lower interfacial protection film that is in contact with the first surface of the second reflective film and a second upper interfacial protection film that is in contact with the second surface of the first reflective film.

7. The photomask blank of claim 6, wherein the first lower interfacial protection film is formed of the same material as that of the second upper interfacial protection film, and
the first upper interfacial protection film is formed of the same material as that of the second lower interfacial protection film.

8. The photomask blank of claim 6, wherein a thickness of the first interfacial protection film is the same as a thickness of the second interfacial protection film.

9. The photomask blank of claim 8, wherein a thickness of the first lower interfacial protection film is the same as a thickness of the first upper interfacial protection film, and
a thickness of the second lower interfacial protection film is the same as a thickness of the second upper interfacial protection film.

10. The photomask blank of claim 1, wherein a wavelength of the exposure light is λ,
a refractive index of molybdenum at the wavelength of the exposure light is n1,
a refractive index of silicon at the wavelength of the exposure light is n2,
a sum of a thicknesses of the first reflective film and a thickness of the first interfacial protection film is λ/(4*n1), and
a sum of a thicknesses of the second reflective film and a thickness of the second interfacial protection film is λ/(4*n2).

11. The photomask blank of claim 1, wherein the capping layer is a ruthenium (Ru) film or a ruthenium compound film.

12. The photomask blank of claim 1, further comprising a light absorbing layer on the capping layer,
wherein the light absorbing layer absorbs the exposure light.

13. A photomask comprising:
a substrate including a first surface on which exposure light used in a photo process is incident, and a second surface opposite to the first surface;
a reflective structure disposed on the first surface of the substrate, and including a first reflective film and a second reflective film which are alternately stacked;
a capping layer on the reflective structure; and
a light absorbing pattern disposed on the capping layer, and including an opening through which the exposure light passes,
wherein the first reflective film is a molybdenum (Mo) film,
the second reflective film is a silicon (Si) film,
each of the first interfacial protection film and the second interfacial protection film includes at least one of molybdenum oxide, silicon oxide, silicon nitride, silicon carbide, boron carbide, or carbon,
each of the first and second reflective films includes a first surface and a second surface which are opposite to each other,
the second surface of the first reflective film and the second surface of the second reflective film face the first surface of the substrate,
the first surface of the first reflective film faces the second surface of the second reflective film, and
the reflective structure includes a first interfacial protection film that is in contact with the first surface of the first reflective film and the second surface of the second reflective film, and a second interfacial protection film that is in contact with the second surface of the first reflective film and the first surface of the second reflective film.

14. The photomask of claim 13, wherein a thickness of the first interfacial protection film is the same as a thickness of the second interfacial protection film.

15. The photomask of claim 14, wherein the thickness of the first interfacial protection film is 0.2 nm or more and 1.0 nm or less.

16. The photomask of claim 13, wherein each of the first interfacial protection film and the second interfacial protection film is a single material film.

17. The photomask of claim 13, wherein the first interfacial protection film includes a first lower interfacial protection film that is in contact with the first surface of the first reflective film, and a first upper interfacial protection film that is in contact with the second surface of the second reflective film,
the second interfacial protection film includes a second lower interfacial protection film that is in contact with the first surface of the second reflective film, and a second upper interfacial protection film that is in contact with the second surface of the first reflective film,
the first lower interfacial protection film is formed of the same material as that of the second upper interfacial protection film, and
the first upper interfacial protection film is formed of the same material as that of the second lower interfacial protection film.

18. The photomask of claim 13, wherein a wavelength of the exposure light is λ,
a refractive index of molybdenum at the wavelength of the exposure light is n1,
a refractive index of silicon at the wavelength of the exposure light is n2,
a sum of a thicknesses of the first reflective film and a thickness of the first interfacial protection film is λ/(4*n1), and
a sum of a thicknesses of the second reflective film and a thickness of the second interfacial protection film is λ/(4*n2).

19. A method of fabricating a semiconductor device, the method comprising:
forming a mask layer on a substrate; and
forming a mask pattern on the substrate by etching the mask layer using a photo process using a photomask,
wherein the photomask includes:
a mask substrate including a first surface on which exposure light used in the photo process is incident, and a second surface opposite to the first surface;
a reflective structure disposed on the first surface of the mask substrate, and including a first reflective film and a second reflective film which are alternately stacked;
a capping layer on the reflective structure; and
a light absorbing pattern arranged on the capping layer, including an opening through which the exposure light passes,
wherein the first reflective film is a molybdenum (Mo) film,
the second reflective film is a silicon (Si) film,
each of the first interfacial protection film and the second interfacial protection film includes at least one of molybdenum oxide, silicon oxide, silicon nitride, silicon carbide, boron carbide, or carbon,
each of the first and second reflective films includes a first surface and a second surface which are opposite to each other,
the second surface of the first reflective film and the second surface of the second reflective film face the first surface of the mask substrate,
the first surface of the first reflective film faces the second surface of the second reflective film, and
the reflective structure includes a first interfacial protection film that is in contact with the first surface of the first reflective film and the second surface of the second reflective film, and a second interfacial protection film that is in contact with the second surface of the first reflective film and the first surface of the second reflective film.
